(19) United States
(12) Patent Application Publication
(10) Pub. No.: US 2024/0260195 A1
(43) Pub. Date: Aug. 1, 2024

(54) EMBEDDED DUAL IN-LINE MEMORY MODULE

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/419,573

(22) Filed: Jan. 23, 2024

(30) Foreign Application Priority Data
Feb. 1, 2023 (TW) 112103424

(51) Int. Cl. H05K 1/18; H01L 23/00; H01L 23/31; H01L 25/00; H01L 25/065; H05K 1/11; H10B 80/00

(52) U.S. Cl. CPC H05K 1/181; H01L 25/0655; H01L 25/50; H01L 23/3121; H01L 24/16; H01L 2224/16225; H05K 1/117; H05K 2201/10159; H05K 2201/10545; H10B 80/00

(57) ABSTRACT

An embedded dual in-line memory module (DIMM) is provided. The memory module includes a printed circuit board (PCB), a first memory chip set, and a second memory chip set. A plurality of memory chips of the first memory chip set is arranged and electrically connected to a first circuit layer of the PCB by flip chip. A plurality of memory chips of the second memory chip set is arranged and electrically connected to a second circuit layer of the PCB by flip chip. The respective chips are directly disposed on the PCB by flip chip. Thereby the memory module has a condition that there is no metal wire for electrical connection generated by wire bonding. This helps cost reduction at manufacturing end and improves electrical performance.

### CROSS-REFERENCE TO RELATED APPLICATIONS

This non-provisional application claims priority under 35 U.S.C. § 119(a) on Patent Application No(s). 112103424 filed in Taiwan, R.O.C. on Feb. 1, 2023, the entire contents of which are hereby incorporated by reference.

### BACKGROUND OF THE INVENTION

The present invention relates to a dual in-line memory module (DIMM), especially to an embedded DIMM in which all electrical connections are formed by flip-chip during manufacturing processes.

Window Ball Grid Array (window BGA) is a type of packaging used for dynamic random access memory (DRAM), also used for manufacturing dual in-line memory module (DIMM) available now. Refer to FIG. 7, a conventional DIMM 2 includes a printed circuit board 2a, a surface 2b, a wire 2c, a chip package set 2d, a read-only memory (ROM) 2f, and a conductive contact 2g. The chip package set 2d consists of a plurality of chip packages 2e each of which is produced by window BGA and composed of a carrier plate 2h, a chip 2i, and an opening 2j. The chip 2i is electrically connected to the carrier plate 2h by metal wires through the opening 2j while the metal wires are produced by wire bonding (not shown in figure). The chip package set 2d is arranged and electrically connected to the wire 2c on the surface 3b of the printed circuit board 2a correspondingly by flip chip.

Thus it is learned that the DIMM available now is produced by the following processes. First a plurality of chips is packaged into a plurality of chip packages by wire bonding (considered as the first packaging process). Then the plurality of chip packages is disposed on a printed circuit board (considered as the second packaging process). Thus the DIMM has the following shortcomings. (1) The manufacturing processes of the DIMM available now include the first and the second packaging processes. Thus electrical connection wires in structure are increased relatively and this leads to poor electrical performance. (2) The manufacturing processes include the first and the second packaging processes so that manufacturing cost at manufacturing end is increased. This doesn't meet requirement for energy reduction now. (3) The first packaging process is completed by wire bonding so that metal wires (such as gold wire) used increase material cost at manufacturing end.

Moreover, the printed circuit board and the chip package of the DIMM available now are exposed so that they are easily damaged. The long term exposure also leads to oxidation of metal materials so that service life is reduced.

### SUMMARY OF THE INVENTION

Therefore, it is a primary object of the present invention to provide an embedded dual in-line memory module (DIMM) which includes a printed circuit board (PCB), a first memory chip set, and a second memory chip set. A plurality of memory chips of the first memory chip set is arranged and electrically connected to a first circuit layer on a first surface of the PCB by flip chip correspondingly. A plurality of memory chips of the second memory chip set is arranged and electrically connected to a second circuit layer on a second surface of the PCB by flip chip correspondingly. The respective memory chips of the memory module are directly disposed on the PCB by flip chip (such as wafer level chip scale package (WLCSP) on DIMM)). Thus the memory module has a condition that there is no metal wire for electrical connection generated by wire bonding. The shortcomings of the DIMM available now can be effectively improved.

In order to achieve the above object, an embedded dual in-line memory module (DIMM) according to the present invention includes a printed circuit board (PCB), a first memory chip set, and a second memory chip set. The PCB consists of a first surface, a second surface opposite to the first surface, a first circuit layer, a second circuit layer, and a conductive contact. The first circuit layer and the second circuit layer are respectively located on the first surface and the second surface. The conductive contact is used for electrical connection to a motherboard of an external electronic device. The first memory chip set is composed of a plurality of memory chips each of which is arranged and electrically connected to the first circuit layer on the first surface of the PCB by flip chip correspondingly. The second memory chip set is composed of a plurality of memory chips each of which is electrically arranged and connected to the second circuit layer on the second surface of the PCB by flip chip correspondingly. The respective memory chips on the memory module are directly disposed on the PCB by flip chip. Thus the memory module has a condition that there is no metal wire for electrical connection generated by wire bonding. A method of manufacturing the memory module includes the following steps. Step S1: providing a printed circuit board (PCB). The PCB consists of a first surface, a second surface opposite to the first surface, a first circuit layer, a second circuit layer, and a conductive contact. The first circuit layer and the second circuit layer are respectively located on the first surface and the second surface. Step S2: arranging and electrically connecting a first memory chip set to the first circuit layer on the first surface of the PCB by flip chip. The first memory chip set includes a plurality of memory chips. Step S3: arranging and electrically connecting a second chip memory chip set to the second circuit layer on the second surface of the PCB by flip chip. Thus manufacturing of a memory module is completed. The second chip memory chip set includes a plurality of memory chips.

Preferably, the memory module further includes a sealing film layer which is covering the memory module by injection molding yet the conductive contact on the PCB of the memory module is exposed.

Preferably, the sealing film layer further includes a flat first surface and a flat second surface opposite to each other. The first surface is located outside the first memory chip set while the second surface is located outside the second memory chip set.

### BRIEF DESCRIPTION OF THE DRAWINGS

FIG. 1 is a schematic drawing showing a top view of an embodiment of a memory module according to the present invention;

FIG. 2 is a schematic drawing showing a side view of an embodiment of a memory module according to the present invention;

FIG. 3 is an exploded side view of an embodiment in which a first memory chip set is arranged and electrically connected to a printed circuit board according to the present invention;

FIG. 4 is a perspective sectional view of an embodiment in which a first memory chip set is arranged and electrically connected to a printed circuit board according to the present invention;

FIG. 5 is an exploded side view of an embodiment in which a second memory chip set is disposed and electrically connected to a printed circuit board according to the present invention;

FIG. 6 is a perspective sectional view of an embodiment in which a second memory chip set is disposed and electrically connected to a printed circuit board according to the present invention;

FIG. 7 is a schematic drawing showing a top view of a dual in-line memory module (DIMM) available now.

### DETAILED DESCRIPTION OF THE PREFERRED EMBODIMENT

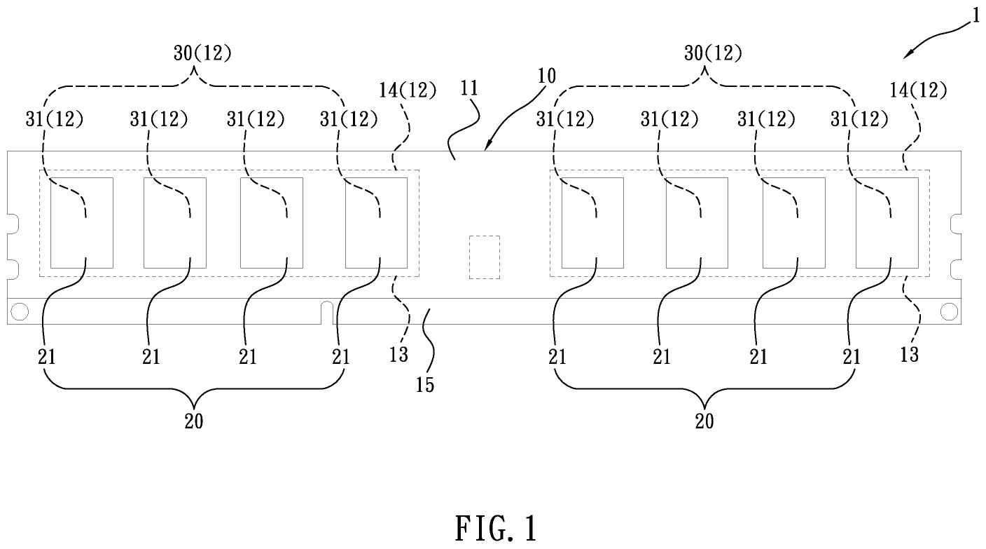

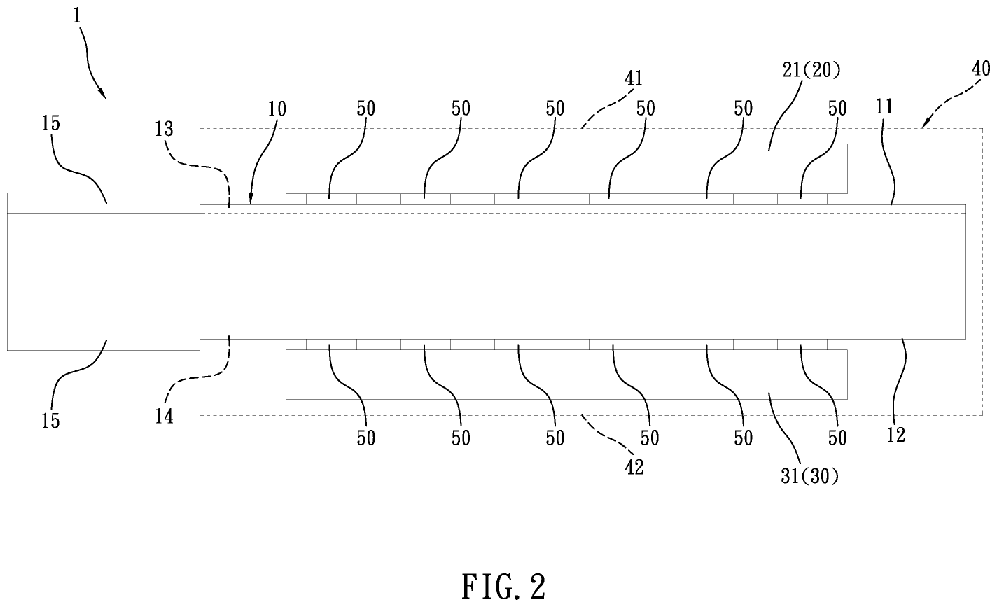

Refer to FIG. 1 and FIG. 2, an embedded dual in-line memory module (DIMM) 1 according to the present invention includes a printed circuit board (PCB) 10, a first memory chip set 20, and a second memory chip set 30.

As shown in FIG. 2, the PCB 10 consists of a first surface 11, a second surface 12 opposite to the first surface 11, a first circuit layer 13, a second circuit layer 14, and a conductive contact 15. The first circuit layer 13 and the second circuit layer 14 are respectively located on the first surface 11 and the second surface 12. The conductive contact 15 is used for electrical connection to a motherboard of an external electronic device such as a server, a workstation, or a personal computer, but not limited.

The first memory chip set 20 is composed of a plurality of memory chips 21 each of which is arranged and electrically connected to the first circuit layer 13 on the first surface 11 of the PCB 10 by flip chip correspondingly, as shown in FIG. 1 and FIG. 2. In the embodiment shown in FIG. 1, the number of the memory chips 21 is 8, but not limited.

The second memory chip set 30 is composed of a plurality of memory chips 31 each of which is disposed and electrically connected to the second circuit layer 14 on the second surface 12 of the PCB 10 by flip chip correspondingly, as shown in FIG. 1 and FIG. 2. In the embodiment shown in FIG. 1, the number of the memory chips 31 is 8, but not limited.

The respective memory chips 21, 31 on the memory module 1 are directly disposed on the PCB 10 by flip chip (such as wafer level chip scale package (WLCSP) on DIMM), as shown in FIG. 2. Thus the memory module 1 has a condition that there is no metal wire (such as gold wire) for electrical connection generated by wire bonding.

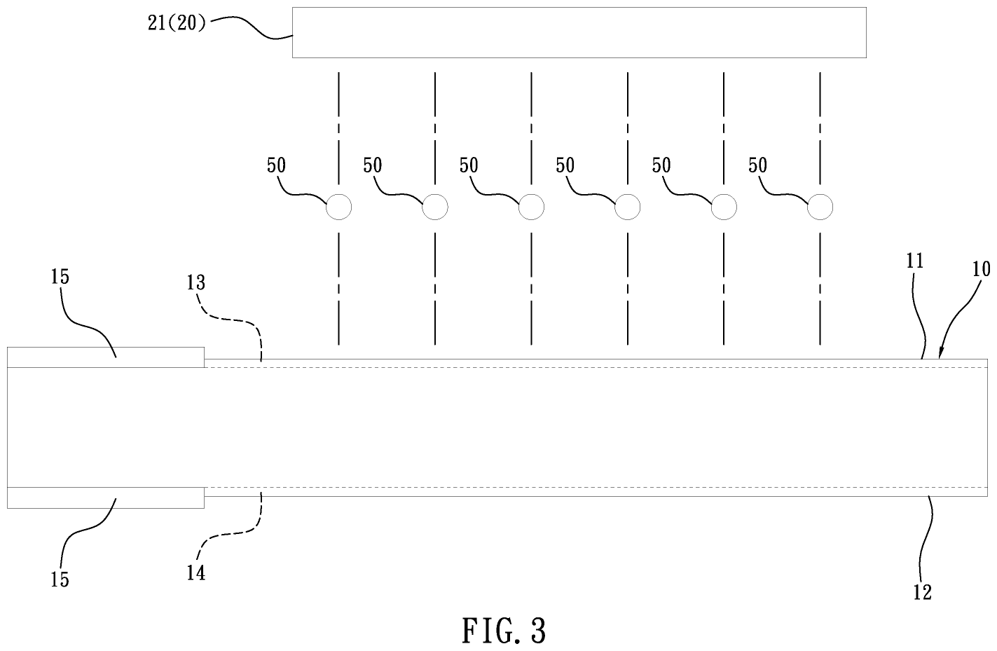

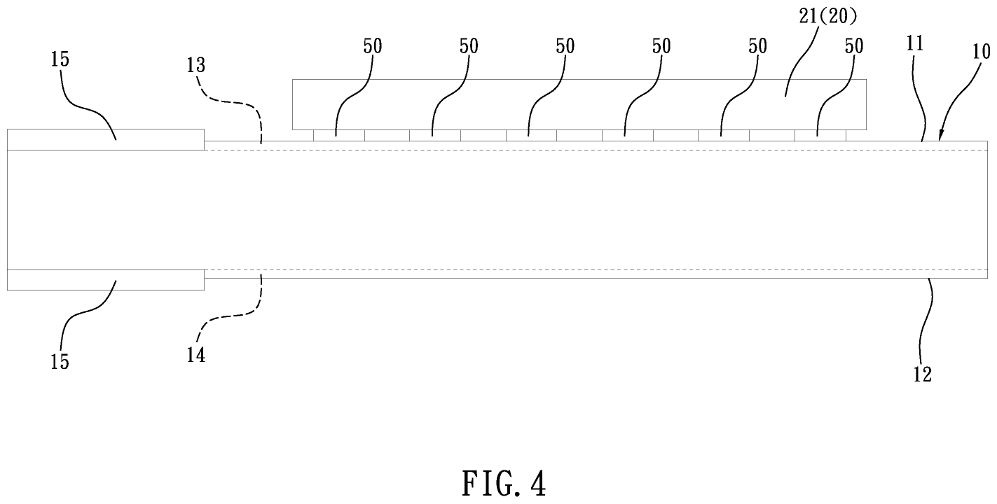

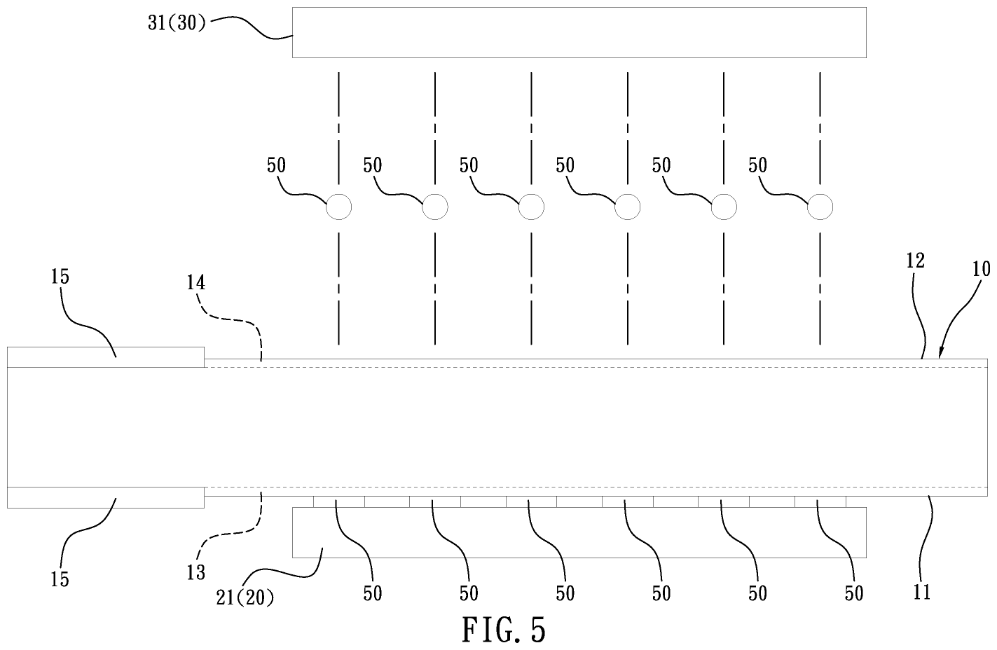

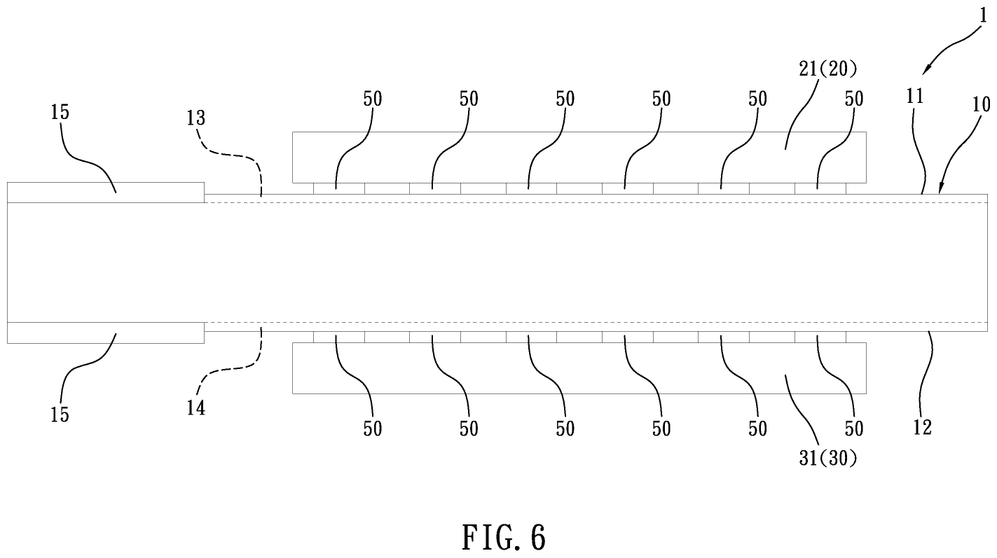

Refer to FIG. 1 and FIG. 3-6, a method of manufacturing the memory modules 1 includes the following steps.
Step S1: providing a printed circuit board (PCB) 10, as shown in FIG. 3. The PCB 10 consists of a first surface 11, a second surface 12 opposite to the first surface 11, a first circuit layer 13, a second circuit layer 14, and a conductive contact 15. The first circuit layer 13 and the second circuit layer 14 are respectively located on the first surface 11 and the second surface 12.
Step S2: arranging and electrically connecting a first memory chip set 20 to the first circuit layer 13 on the first surface 11 of the PCB 10 by flip chip, as shown in FIG. 3 and FIG. 4. The first memory chip set 20 includes a plurality of memory chips 21, as shown in FIG. 1.
Step S3: arranging and electrically connecting a second chip memory chip set 30 to the second circuit layer 14 on the second surface 12 of the PCB 10 by flip chip, as shown in FIG. 5 and FIG. 6. Thus production of a memory module 1 is completed. The second chip memory chip set 30 includes a plurality of memory chips 31, as shown in FIG. 1.

The respective memory chips 21 are welded on the first circuit layer 13 by at least one solder ball 50, as shown in FIG. 3. The respective memory chips 31 are welded on the second circuit layer 14 by at least one solder ball 50, as shown in FIG. 5.

Refer to FIG. 2, the memory module 1 further includes a sealing film layer 40 which is covering the memory module 1 by injection molding yet the conductive contact 15 on the PCB 10 of the memory module 1 is exposed. The sealing film layer 40 further includes a flat first surface 41 and a flat second surface 42 opposite to each other, as shown in FIG. 2. The first surface 41 is located outside the first memory chip set 20 while the second surface 42 is located outside the second memory chip set 30, as shown in FIG. 2.

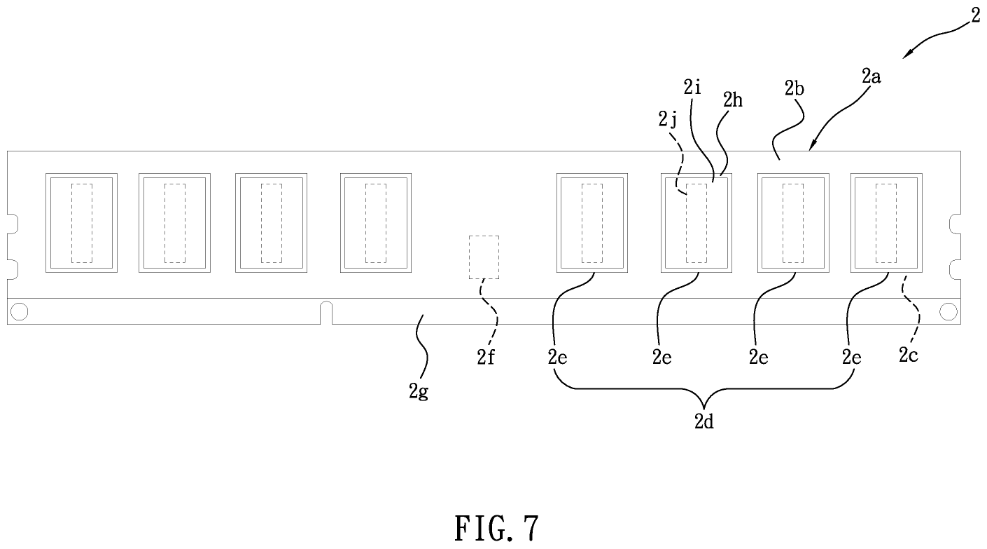

Compared with the memory module (DIMM) 2 available now (as shown in FIG. 7), the respective memory chips 21, 31 on the present memory module 1 are directly disposed on the PCB 10 by flip chip, as shown in FIG. 2. In the memory module 2 available now (as shown in FIG. 7), a plurality of chips is packaged by wire bonding to form a plurality of chip packages (the first packaging process). Then the plurality of chip packages is packaged on the printed circuit board (the second packaging process). Therefore, the memory module 1 (as shown in FIG. 1) according to the present invention has the following advantages.
(1) The respective memory chips 21, 31 are directly disposed on the PCB 10 by flip chip so that connecting circuit between electronic components is shortened and electrical performance between the electronic components is good.
(2) Production of the memory module 1 is completed by only one packaging process so that manufacturing cost at manufacturing end is reduced.
(3) The manufacturing process of the memory module 1 doesn't include wire bonding so that no metal wires (such as gold wires) are used at manufacturing end. This helps reduction of material cost at the manufacturing end.

Moreover, the present memory module 1 further includes the sealing film layer 40, as shown in FIG. 2. The sealing film layer 40 is covering the memory module 1 by injection molding but the conductive contact 15 on the PCB 10 of the memory module 1 is exposed. The shortcoming of the chip and the circuit exposed such as easily damaged or oxidized can be avoided. A yield rate and service life of products are increased and this is beneficial to improving product competitiveness in the market.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. An embedded dual in-line memory module (DIMM) comprising:
a printed circuit board (PCB) which includes a first surface, a second surface opposite to the first surface, a first circuit layer on the first surface, a second circuit layer on the second surface, and a conductive contact used for electrical connection to a motherboard of an external electronic device;
a first memory chip set composed of a plurality of memory chips each of which is arranged and electrically connected to the first circuit layer on the first surface of the PCB by flip chip correspondingly; and
a second memory chip set provided with a plurality of memory chips each of which is electrically disposed and connected to the second circuit layer on the second surface of the PCB by flip chip correspondingly;
wherein the respective memory chips on the memory module are directly disposed on the PCB by flip chip so that the memory module has a condition that there is no metal wire for electrical connection generated by wire bonding;
wherein a method of manufacturing the memory module comprising the following steps of:
Step S1: providing a printed circuit board (PCB). The PCB consists of a first surface, a second surface opposite to the first surface, a first circuit layer on the first surface, a second circuit layer on the second surface, and a conductive contact;
Step S2: arranging and electrically connecting a first memory chip set to the first circuit layer on the first surface of the PCB by flip chip; wherein the first memory chip set includes a plurality of memory chips; and
Step S3: arranging and electrically connecting a second chip memory chip set to the second circuit layer on the second surface of the PCB by flip chip so that manufacturing of a memory module is completed; wherein the second chip memory chip set includes a plurality of memory chips.

2. The memory module as claimed in claim 1, wherein the memory module further includes a sealing film layer which is covering the memory module by injection molding but the conductive contact on the PCB of the memory module is exposed.

3. The memory module as claimed in claim 2, wherein the sealing film layer further includes a flat first surface and a flat second surface opposite to each other; wherein the first surface is located outside the first memory chip set while the second surface is located outside the second memory chip set.
